(19) United States
(12) Patent Application Publication
(10) Pub. No.: US 2024/0136236 A1
(43) Pub. Date: Apr. 25, 2024

(54) VERTICAL SEMICONDUCTOR COMPONENT AND METHOD FOR GENERATING AN ABRUPT END POINT DETECTION SIGNAL DURING THE PRODUCTION OF SUCH A VERTICAL SEMICONDUCTOR COMPONENT

(71) Applicant: Robert Bosch GmbH, Stuttgart (DE)

(72) Inventors: Christian Huber, Ludwigsburg, DE (US); Roland Puesche, Rommelsbach, DE (US)

(21) Appl. No.: 18/546,168

(22) PCT Filed: Jan. 28, 2022
(86) PCT No.: PCT/EP2022/052027

§ 371 Date: Aug. 10, 2023

(30) Foreign Application Priority Data
Mar. 30, 2021 (DE) 10 2021 203 271.0

(51) Int. Cl. H01L 21/66; H01J 37/32; H01L 29/417; H01L 29/66; H01L 29/78

(52) U.S. Cl. CPC H01L 22/26; H01J 37/32963; H01L 29/41741; H01L 29/66734; H01L 29/7813; H01J 2237/334; H01L 29/2003

(57) ABSTRACT

A vertical semiconductor component for generating an abrupt end point detection signal. The vertical semiconductor component includes: a semiconductor substrate which has a front face and a rear face, the front face being opposite the rear face, and the semiconductor substrate having first chemical elements; a buffer layer which is arranged on the front face of the semiconductor substrate, the buffer layer having second chemical elements; and a semiconductor contact layer which is arranged on the buffer layer, an active region of the vertical semiconductor component being arranged on the semiconductor contact layer. An etching control layer is arranged between the buffer layer and the semiconductor contact layer, the etching control layer having at least one third chemical element which differs from the first chemical elements and the second chemical elements.

### FIELD

The present invention relates to a vertical semiconductor component and a method for generating an abrupt end point detection signal during the production of such a semiconductor component.

### BACKGROUND INFORMATION

Vertical semiconductor components based on gallium nitride and arranged on silicon substrates require buffer layers to adjust the lattice mismatch between GaN and Si and to reduce the substrate curvature. The buffer layers are stressed in such a way that they compensate for the stresses of the GaN layers. The buffer layers prevent current flow from the front face to the rear face of the semiconductor component, since the buffer layers are electrically insulating. In order to prevent this insulation, the non-conductive buffer layer is selectively removed with the aid of a rear-face trench below the semiconductor component, so that the rear face of the drift zone of the semiconductor component can be contacted by means of an ohmic metal semiconductor contact to a semiconductor contact layer located under the drift zone.

A disadvantage here is that the determination of the time at which the non-conductive buffer layer is completely removed and etching of the semiconductor contact layer begins is difficult to ascertain. If the rear-face trench ends within the buffer layer due to premature termination of the removal process, no vertical current flow takes place. If the rear-face trench ends within the drift layer, the on-resistance of the semiconductor component is too high and the breakdown voltage of the semiconductor component is low.

An object of the present invention is to overcome this disadvantage.

### SUMMARY

According to an example embodiment of the present invention, the vertical semiconductor component comprises a semiconductor substrate which has a front face and a rear face, the front face being opposite the rear face. The semiconductor substrate has first chemical elements. A buffer layer which has second chemical elements is arranged on the front face of the semiconductor substrate. A semiconductor contact layer is arranged on the buffer layer, a vertical semiconductor component being arranged on the semiconductor contact layer. According to the present invention, an etching control layer is arranged between the buffer layer and the semiconductor contact layer. The etching control layer has at least one third chemical element, which differs from the first chemical elements and the second chemical elements. In other words, the third chemical element is present in a significant concentration neither in the buffer layer nor in the semiconductor substrate.

An advantage here is that the semiconductor contact layer can be very thin, with the on-resistance of the vertical semiconductor component being low. In addition, the total thickness of the epitaxial layer stack is small, as a result of which the process costs are low, since few compensation layers for mechanical stresses have to be produced.

In one embodiment of the present invention, the third element comprises germanium, magnesium, iron or indium.

It is advantageous here that these elements can simply be incorporated into the etching control layer as a doping element by means of common precursor gases in an epitaxial growth process without thereby reducing the crystal quality of the overlying layers. The advantage when germanium is used is that germanium has an n-doping effect.

According to an example embodiment of the present invention, the vertical semiconductor component comprises a semiconductor substrate which has a front face and a rear face, the front face being opposite the rear face, and the semiconductor substrate comprises first chemical elements and a further chemical element with a first background concentration. A buffer layer is arranged on the front face of the semiconductor substrate, the buffer layer having second chemical elements and the further chemical element with a second background concentration. A semiconductor contact layer is arranged on the buffer layer, an active region of the vertical semiconductor component being arranged on the semiconductor contact layer. According to the present invention, an etching control layer is arranged between the buffer layer and the semiconductor contact layer. The etching control layer comprises the further chemical element with a third background concentration. The third background concentration is greater than the first background concentration and the second background concentration.

In one example embodiment of the present invention, the further chemical element is carbon.

It is advantageous here that the crystal quality is not impaired.

In one development of the present invention, the third background concentration comprises a range between 1E18 cm\hat{ }−3 and 1E19 cm\hat{ }−3.

An advantage here is that high carbon concentrations can easily be realized during the epitaxial growth of the etching control layer.

In one development of the present invention, the etching control layer has a layer thickness between 20 nm and 200 nm.

An advantage is that, with such a layer thickness, it can easily be detected by means of common end point detection methods that the layer has been reached and removed during the generation of the rear face trench. At the same time, this choice of layer thickness of the etching control layer means that the additional outlay for the growth of the etching control layer is low.

In a further embodiment of the present invention, the first chemical elements comprise silicon, silicon and boron, silicon and phosphorus, silicon and arsenic or silicon and antimony, and the second chemical elements comprise aluminum and gallium and nitrogen.

In a further embodiment of the present invention, the vertical semiconductor component has gallium nitride.

An advantage is that a semiconductor component having a high breakdown voltage can be realized with low specific on-resistance and low switching losses.

In one embodiment of the present invention, the vertical semiconductor component is a Schottky diode, a pn diode, a vertical diffusion MOSFET, a planar gate MOSFET, a trench gate MOSFET, a current aperture vertical electron transistor, a vGroove HEMT or a FinFET.

A method according to an example embodiment of the present invention for generating an abrupt end point detection signal during the production of a vertical semiconductor component, the vertical semiconductor component comprising: a semiconductor substrate having a front face and a rear face, the front face being opposite the rear face, and the semiconductor substrate having first chemical elements; a buffer layer arranged on the semiconductor substrate, the buffer layer having second chemical elements; a semiconductor contact layer and an active region of the vertical semiconductor component, comprises: generating an etching control layer which is arranged between the buffer layer and the semiconductor contact layer, the etching control layer comprising a third chemical element which differs from the first chemical elements and the second chemical elements. Furthermore, the method comprises generating a rear-face trench with the aid of an etching process, the rear-face trench extending from the rear face of the semiconductor substrate toward the semiconductor contact layer, detecting an abrupt end point detection signal with the aid of an end point detection system, and terminating the etching operation depending on the end point detection signal.

An advantage here is that the etching process can be stopped in a targeted manner at the junction to the semiconductor contact layer, since it is possible to detect when this layer is reached by means of common end point detection methods.

Further advantages can be found in the following description of exemplary embodiments of the present invention and the disclosure herein.

### BRIEF DESCRIPTION OF THE DRAWINGS

The present invention is explained below with reference to preferred embodiments and the figures.

FIG. 1 shows a vertical semiconductor component from the related art.

FIG. 2 shows a vertical semiconductor component according an example embodiment of the present invention.

FIG. 3 shows a method for generating an abrupt end point detection signal during the production of a vertical semiconductor component according to an example embodiment of the present invention.

FIG. 4 shows an exemplary first signal sequence of an end point signal and an exemplary second signal sequence of the end point signal during an etching process for the production of a rear-face trench in the production of a vertical semiconductor component according to an example embodiment of the present invention.

### DETAILED DESCRIPTION OF EXAMPLE EMBODIMENTS

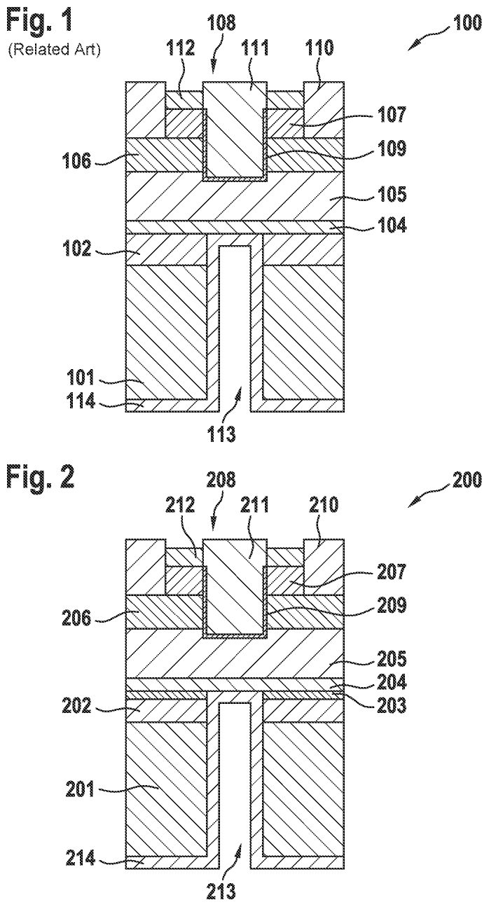

FIG. 1 shows a vertical semiconductor component 100 from the related art. The vertical semiconductor component 100 comprises a semiconductor substrate 101 which has a front face and a rear face, the front face being opposite the rear face. A buffer layer 102 is arranged on the front face. A semiconductor contact layer 104 is arranged on the buffer layer 102. The semiconductor contact layer 104 is highly doped and n-conductive. An active region of the vertical semiconductor component is arranged on the semiconductor contact layer 104. In this case, the vertical semiconductor component is, by way of example, a unit cell of a MOSFET and has GaN. The active region of the vertical semiconductor component 100 comprises a drift layer 105 arranged on the semiconductor contact layer 104. The drift layer 105 is low-doped and n-conductive. A body layer 106 is arranged on the drift layer 105. The body layer 106 is p-conductive. Source contact regions 107 and the source electrode 110 are arranged on the body layer 106. The source contact regions 107 are highly doped and n-conductive. An insulation region 112 is arranged on the source contact regions 107. Starting from the insulation regions 112, a front-face trench 108 extends toward the rear face and ends within the drift layer 105. A gate dielectric 109 is applied on the front-face trench 108. The front-face trench 108 is filled with the gate electrode 111. Starting from the rear face, a rear-face trench 113 extends toward the front face. A drain electrode 114 is arranged on the rear face.

During operation of the vertical semiconductor component 100, a conductive channel is formed in the body layer 106 by applying a gate voltage to the gate electrode 111, so that a current flows between the source electrode 110 and the drain electrode 114. In order to be able to ensure a low on-resistance of the vertical semiconductor component 100, the rear-face trench 113 must end within the contact semiconductor layer 104. Due to the process tolerances and process control when the etching causing the removal of the buffer layer 102 in some regions is stopped, the thickness of the semiconductor contact layer 104 must be selected to be very large. The thickness comprises, for example, a range between 500 nm and 1 μm, in particular slightly more than 500 nm, for example greater than 500 nm.

The semiconductor substrate 101 comprises silicon, and the buffer layer 102 comprises gallium, nitrogen and aluminum. The semiconductor contact layer 104 comprises gallium, nitrogen and silicon. For an end point signal, only the elements gallium, aluminum, nitrogen and silicon can thus be detected by the end point detection system. Since the buffer layer 102 and the semiconductor contact layer 104 have the same chemical elements, a clear, abrupt end point signal cannot be generated. Although silicon is not present in the buffer layer 102, the silicon generates a high background signal from the semiconductor substrate 101, and therefore an abrupt end point signal cannot be generated with the aid of this chemical element either, as a result of which the semiconductor contact layer 104 must be selected to be very thick in order to prevent overetching of the semiconductor contact layer.

FIG. 2 shows a vertical semiconductor component 200 according to the present invention. The vertical semiconductor component 200 comprises a semiconductor substrate 201 which has a front face and a rear face, the front face being opposite the rear face. The semiconductor substrate 201 has first chemical elements. A buffer layer 202 which has second chemical elements is arranged on the front face. An etching control layer 203 is arranged on the buffer layer 202. The etching control layer 203 has at least one third chemical element. The third chemical element differs from the first chemical elements and the second chemical elements. A semiconductor contact layer 204 is arranged on the etching control layer 203. The semiconductor contact layer 204 is highly doped and n-conductive. An active region of the vertical semiconductor component is arranged on the semiconductor contact layer 204. The vertical semiconductor component 200 is shown here by way of example as a unit cell of a MOSFET and comprises gallium nitride. The active region of the vertical semiconductor component 200 has a drift layer 205 arranged on the semiconductor contact layer 204. The drift layer 205 is low-doped and n-conductive. A body layer 206 is arranged on the drift layer 205. The body layer 206 is p-conductive. Source contact regions 207 and the source electrode 210 are arranged on the body layer 206. The source contact regions 207 are highly doped and n-conductive. An insulation region 212 is arranged on the source contact regions 207. Starting from the insulation regions 212, a front-face trench 208 extends toward the rear face and ends within the drift layer 205. A gate dielectric 209 is applied on the front-face trench 208. The front-face trench 208 is filled with the gate electrode 211. Starting from the rear face, a rear-face trench 213 extends toward the front face. A drain electrode 214 is arranged on the rear face.

The semiconductor substrate 201 comprises first chemical elements such as silicon, silicon and boron, silicon and phosphorus, silicon and arsenic, or silicon and antimony. The buffer layer 202 comprises second chemical elements such as aluminum, gallium and nitrogen and can consist of multiple individual layers with different stoichiometry of these second elements. The etching control layer 203 comprises doped gallium nitride. The etching control layer 203 is doped with at least one third chemical element, for example germanium, magnesium, iron, indium or carbon. Preferably, germanium is present, since this additionally has an n-doping effect, so that even when the etching control layer 203 is not completely removed, a vertical flow of current from the front face to the rear face of the vertical semiconductor component 200 is possible.

The etching control layer 203 has a layer thickness between 20 nm and 200 nm. In addition, the etching control layer 203 preferably comprises the same lattice structure and a similar lattice constant as the semiconductor contact layer 204. The semiconductor contact layer 204 comprises silicon-doped gallium nitride and has a dopant concentration greater than 1e18 1/cm\hat{ }3.

In addition, further etching control layers can be inserted within the buffer layer 201 or between the buffer layer 201 and the semiconductor contact layer 204 in order to obtain further information about the etching depth of the rear-face trench.

In a further exemplary embodiment, the semiconductor substrate 201 additionally comprises, in addition to the first chemical elements, a further chemical element with a first background concentration. The buffer layer additionally comprises, in addition to the second chemical elements, the further chemical element with a second background concentration. The first background concentration and the second background concentration can be the same. The etching control layer 203 has the further chemical element with a third background concentration. The third background concentration is higher than the first background concentration and the second background concentration. The further chemical element is carbon. Due to the process, carbon is present in a low concentration in the semiconductor substrate 201 and in a significant concentration in the buffer layer 202, for example in a concentration of approximately 1e17 1/cm\hat{ }3 in an aluminum-containing buffer layer 202, and can be regarded there as a background element. The carbon can have a concentration of up to 1E19 1/cm\hat{ }3 in the etching control layer 203 without impairing the crystal quality. Due to the difference in the concentration of carbon in the buffer layer 202 and in the etching layer 203, an abrupt end point signal is generated when the semiconductor contact layer 204 is reached.

The highly doped semiconductor contact layer 204 is thinner than the related art in FIG. 1. The semiconductor contact layer 204 has a layer thickness between 100 nm and 500 nm. This means that the safety buffer for dry-chemical overetching is smaller.

The total thickness of a GaN layer stack on silicon is technologically limited. Due to the thinner semiconductor contact layer 204, the drift layer 205 can be increased such that the vertical semiconductor component 200 can have a higher blocking voltage.

The vertical semiconductor component 200 can be designed as a Schottky diode, pn diode, vertical diffusion MOSFET, planar gate MOSFET, trench gate MOSFET, current aperture vertical electron transistor, vGroove HEMT or FinFET. The vertical semiconductor component 200 can also comprise multiple unit cells of a transistor over one or more rear-face trenches.

The vertical semiconductor component 200 is used in the electric drive train of electric or hybrid vehicles, for example in the DC/DC converter or inverter, and in vehicle-charging devices or inverters for domestic appliances.

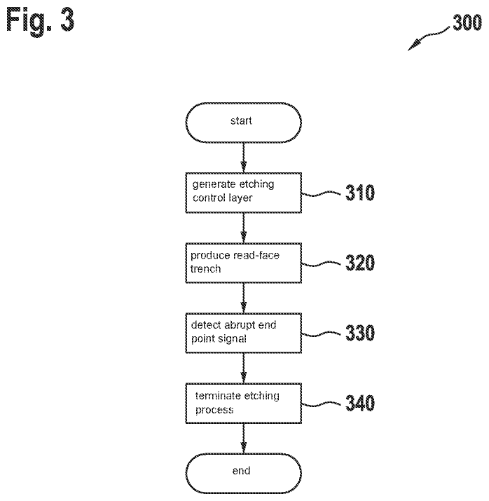

FIG. 3 shows a method 300 according to the present invention for generating an abrupt end point detection signal during the production of a vertical semiconductor component according to the present invention, the vertical semiconductor component comprising: a semiconductor substrate which has a front face and a rear face, the front face being opposite the rear face, and the semiconductor substrate having first chemical elements; a buffer layer which is arranged on the semiconductor substrate and has second chemical elements; a semiconductor contact layer and an active region of the vertical semiconductor component. The method 300 starts with step 310, in which an etching control layer is generated on the buffer layer, the etching control layer having a third element which differs from the first chemical elements and the second chemical elements. The etching control layer is generated epitaxially. In a subsequent step 320, a rear-face trench is produced with the aid of an etching process, the rear-face trench extending from the rear face of the semiconductor substrate toward the semiconductor contact layer. In a subsequent step 330, the abrupt end point signal is detected with the aid of an end point detection system. In a subsequent step 340, the etching process is terminated depending on the end point detection signal.

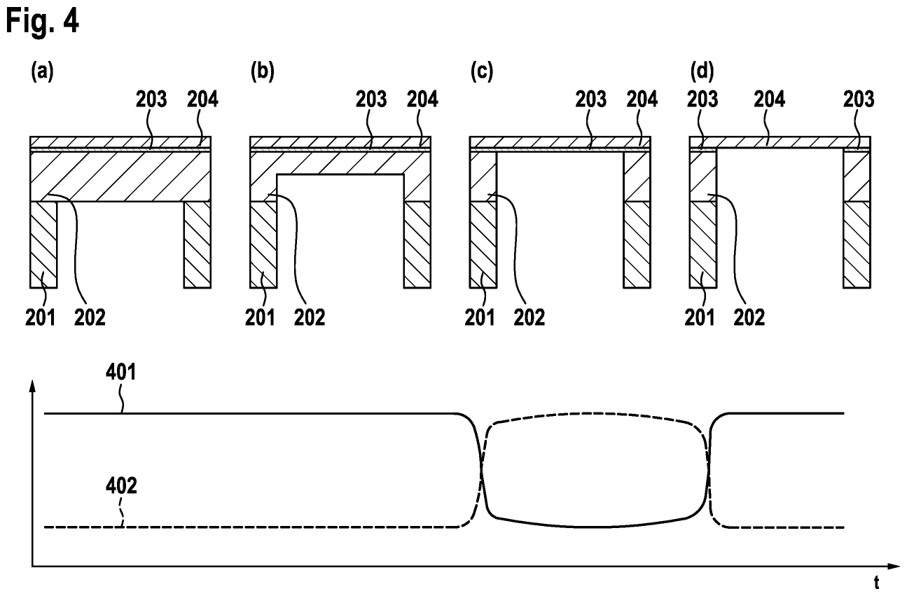

FIG. 4 shows, by way of example, a first signal sequence 401 of an end point signal of an optical emission spectroscopy process, in which the signal of an absorption line of a gaseous compound comprising the third chemical element or the further chemical element originates, and a second signal sequence 402 of a secondary ion mass spectrometry process, in which the etched element is detected on the basis of its mass. Also shown is the etching progress in a cross-sectional view of the semiconductor component at four times a, b, c and d. Dry chemical etching is carried out, for example, by means of chlorine-containing gases in a capacitively or inductively coupled plasma etching system. Dry physical etching takes place, for example, with argon ion bombardment. At the beginning of the etching and during the etching of the buffer layer at the times a and b, the end point signals 401 and 402 remain constant, since no material is etched out of the etching control layer or brought into the gas phase. The etching conditions must be selected such that they are not selective between GaN and AlN. As soon as the etching control layer is reached at the time c, the end point signals 401 and 402 change abruptly. At this time c, the etching processes can also already be changed, by changing etching conditions which lead to slower, controlled etching, so-called soft landing. After complete removal of the etching control layer at the time d, the end point signals 401 and 402 return to their original or virtually original values. The actual signal sequences of the end point detection systems can also use derivatives of the end point signals. It is relevant that a clear, abrupt end point signal, which allows the exact detection of the time at which the semiconductor contact layer is reached, is generated by the etching control layer.

1-10. (canceled)

11. A vertical semiconductor component for generating an abrupt end point detection signal, comprising:
a semiconductor substrate which has a front face and a rear face, the front face being opposite the rear face, the semiconductor substrate having first chemical elements;
a buffer layer which is arranged on the front face of the semiconductor substrate, the buffer layer having second chemical elements;
a semiconductor contact layer which is arranged on the buffer layer, an active region of the vertical semiconductor component being arranged on the semiconductor contact layer; and
an etching control layer arranged between the buffer layer and the semiconductor contact layer, the etching control layer having at least one third chemical element which differs from the first chemical elements and the second chemical elements.

12. The vertical semiconductor component according to claim 11, wherein the third chemical element includes germanium, or magnesium, or iron or indium.

13. A vertical semiconductor component for generating an abrupt end point detection signal, comprising:
a semiconductor substrate which has a front face and a rear face, the front face being opposite the rear face, the semiconductor substrate having first chemical elements and a further chemical element with a first background concentration,
a buffer layer which is arranged on the front face of the semiconductor substrate, the buffer layer having second chemical elements and the further chemical element with a second background concentration;
a semiconductor contact layer which is arranged on the buffer layer, an active region of the vertical semiconductor component being arranged on the semiconductor contact layer; and
an etching control layer arranged between the buffer layer and the semiconductor contact layer, the etching control layer having the further element with a third background concentration, the third background concentration being greater than the first background concentration and the second background concentration.

14. The vertical semiconductor component according to claim 13, wherein the further chemical element is carbon.

15. The vertical semiconductor component according to claim 13, wherein the third background concentration includes a range between 1E18 cm\hat{ }−3 and 1E19 cm\hat{ }−3.

16. The vertical semiconductor component according to claim 11, wherein the etching control layer has a layer thickness between 20 nm and 200 nm.

17. The vertical semiconductor component according to claim 11, wherein the first chemical elements include: i) silicon, or ii) silicon and boron, or iii) silicon and phosphorus, or iv) silicon and arsenic, or v) silicon and antimony, and the second chemical elements include aluminum and gallium and nitrogen.

18. The vertical semiconductor component according to claim 11, wherein the vertical semiconductor component includes gallium nitride.

19. The vertical semiconductor component according to claim 11, wherein the vertical semiconductor component is a Schottky diode, or a pn diode, or a vertical diffusion MOSFET, or a planar gate MOSFET, or a trench gate MOSFET, or a current aperture vertical electron transistor, or a vGroove HEMT, or a FinFET.

20. A method for generating an abrupt end point detection signal during production of a vertical semiconductor component including a semiconductor substrate which has a front face and a rear face, the front face being opposite the rear face, the semiconductor substrate having first chemical elements, the vertical semiconductor component further including a buffer layer which is arranged on the semiconductor substrate and has second chemical elements, the vertical semiconductor component further includes a semiconductor contact layer, and an active region of the vertical semiconductor component, the method comprising the following steps:
generating an etching control layer which is arranged between the buffer layer and the semiconductor contact layer, the etching control layer having a third chemical element which differs from the first chemical elements and the second chemical elements;
generating, using an etching process, a rear-face trench extending from the rear face of the semiconductor substrate toward the semiconductor contact layer;
detecting the abrupt end point detection signal using an end point detection system; and
terminating the etching process depending on the end point detection signal.
